(19) United States
(12) Patent Application Publication
(10) Pub. No.: US 2006/0237747 A1
(43) Pub. Date: Oct. 26, 2006

(54) Heterojunction bipolar transistor and amplifier including the same

(75) Inventors: Satoshi Suzuki, Tokyo (JP); Yoshitsugu Yamamoto, Tokyo (JP); Nobuyuki Ogawa, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/392,572

(22) Filed: Mar. 30, 2006

(30) Foreign Application Priority Data
Apr. 21, 2005 (JP) 2005-123525

(51) Int. Cl. H01L 31/00

(52) U.S. Cl. 257/198

(57) ABSTRACT

An N-type collector layer is partially formed on an N⁺-type collector contact layer. The N-type collector layer includes a second N-type collector layer that is partially formed on the N⁺-type collector contact layer and relatively hard to deplete, and a first N-type collector layer that is formed on the whole surface of the second N-type collector layer and depleted relatively easily. A P⁺-type base layer including a high concentration P-type impurity is formed on the whole surface of the first N-type collector layer.

### BACKGROUND OF THE INVENTION

1. Field of the Invention

This invention relates to heterojunction bipolar transistors, and more particularly to techniques of reducing collector voltage dependence of a gain in amplifiers including the heterojunction bipolar transistors.

2. Description of the Background Art

In heterojunction bipolar transistors used in conventional common-emitter type high output amplifiers, a collector layer is designed to have a prescribed impurity concentration and a sufficient thickness to ensure that a predetermined desired gain is obtained under normal operation, and that the ON breakdown voltage is secured under operation at the highest conceivable power supply voltage (collector voltage). Such heterojunction bipolar transistors are illustrated in Japanese Patent Application Nos. 4-93035 (1992), 5-190562 (1993) and 2003-218123, for example.

When the collector voltage is reduced from a voltage value under normal operation, however, a depletion layer thickness in the collector layer decreases compared with that under normal operation, increasing capacitance between a base and a collector as feedback capacitance between an input and an output. This causes a gain in the amplifiers to be reduced from the predetermined value.

### SUMMARY OF THE INVENTION

It is an object of this invention to provide a heterojunction bipolar transistor capable of reducing collector voltage dependence of a gain.

In an aspect of the invention, a heterojunction bipolar transistor includes a first conductivity type collector layer, a first conductivity type emitter layer, and a second conductivity type base layer interposed between the first conductivity type collector layer and the first conductivity type emitter layer. The first conductivity type collector layer includes a first conductivity type first collector layer, and a first conductivity type second collector layer. The first conductivity type first collector layer makes contact with the second conductivity type base layer. The first conductivity type second collector layer makes contact with the first conductivity type first collector layer. The first conductivity type first collector layer is entirely depleted upon being supplied with a lowest collector voltage which is the lowest conceivable collector voltage to be used. The first conductivity type second collector layer has a carrier concentration higher than space charge concentration based on a normal collector voltage, and a depletion layer formed therein upon being supplied with the normal collector voltage, the ratio of the thickness of the depletion layer being not more than 20% with reference to the thickness of a depletion layer formed in the whole of the first conductivity type collector layer.

A depletion layer thickness of the first conductivity type collector layer hardly decreases even when the collector voltage is reduced from the normal collector voltage to the lowest collector voltage. This prevents a significant increase in depletion layer capacitance that accompanies depletion, which is capacitance between a base and a collector as feedback capacitance between an input and an output. Accordingly, a gain is prevented from being reduced significantly from a predetermined value in a common-emitter type high output amplifier including the heterojunction bipolar transistor as an amplifying element. Namely, the collector voltage dependence of a gain in the common-emitter type high output amplifier can be reduced.

These and other objects, features, aspects and advantages of this invention will become more apparent from the following detailed description of this invention when taken in conjunction with the accompanying drawings.

### BRIEF DESCRIPTION OF THE DRAWINGS

FIG. 1 is a cross-sectional view illustrating the structure of a heterojunction bipolar transistor (HBT) according to a first preferred embodiment of this invention;

FIG. 2 depicts impurity concentration profiles of the HBT;

FIG. 3 is a graph illustrating the collector current-collector voltage characteristic of the HBT;

FIGS. 4 and 5 illustrate band diagrams of the HBT;

FIG. 6 is a graph illustrating the relationship between a collector voltage and a gain in a common-emitter type high output amplifier formed by using the HBT;

FIG. 7 is a cross-sectional view illustrating the structure of a heterojunction bipolar transistor (HBT) according to a second preferred embodiment of this invention;

FIG. 8 depicts impurity concentration profiles of the HBT; and

FIG. 9 illustrates band diagrams of the HBT.

### DESCRIPTION OF THE PREFERRED EMBODIMENTS

A heterojunction bipolar transistor according to this invention includes an N-type collector layer of double-layer structure consisting of an N-type collector layer that is depleted relatively easily and an N-type collector layer that is relatively hard to deplete.

Preferred embodiments of this invention will be described with reference to the drawings, which are based on a common-emitter type high output amplifier using an NPN-type heterojunction bipolar transistor.

### First Preferred Embodiment

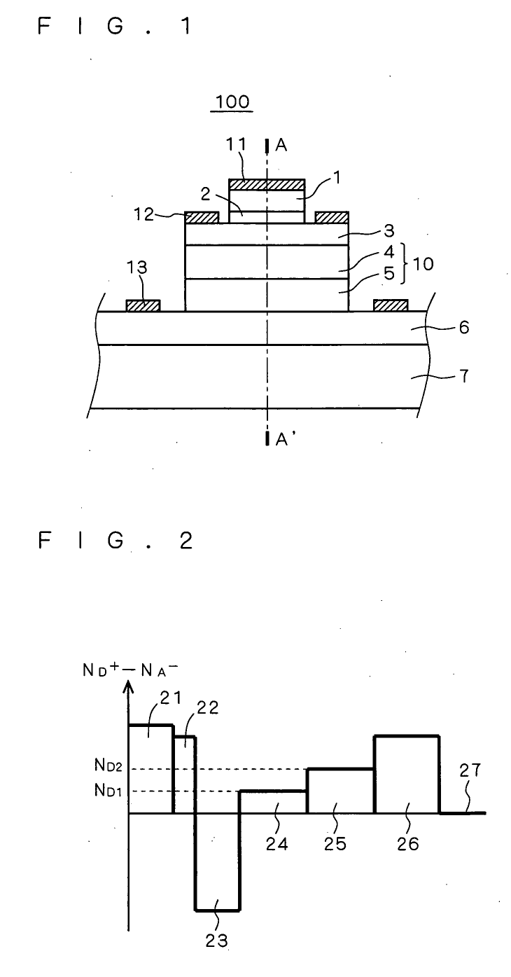

FIG. 1 is a cross-sectional view illustrating the structure of a heterojunction bipolar transistor (hereafter referred to as an “HBT”) 100 according to a first preferred embodiment of this invention.

In FIG. 1, an N⁺-type collector contact layer 6 (fist conductivity type high carrier concentration collector contact layer) including a high concentration N-type impurity is formed on a semi-insulation substrate 7. Collector electrodes 13 and an N-type collector layer 10 (first conductivity type collector layer) are partially formed on the N⁺-type collector contact layer 6. The N-type collector layer 10 includes an N-type collector layer 5 (first conductivity type second collector layer) partially formed on the N⁺-type collector contact layer 6, and an N-type collector layer 4 (first conductivity type first collector layer) formed on the whole surface of the N-type collector layer 5. The N-type collector layers 4 and 5 are different from each other in impurity concentration and thickness, but are the same in the other characteristics (such as saturated velocity of electrons in the material and permittivity of the material).

A P⁺-type base layer 3 (second conductivity type base layer) including a high concentration P-type impurity is formed on the whole surface of the N-type collector layer 4. Base electrodes 12 and an N-type emitter layer 2 (first conductivity type emitter layer) are partially formed on the P⁺-type base layer 3. An N⁺-type emitter contact layer 1 including a high concentration N-type impurity is formed on the whole surface of the N-type emitter layer 2. An emitter electrode 11 is formed on the whole surface of the N⁺-type emitter contact layer 1.

When the HBT 100 forms a common-emitter type high output amplifier, the emitter electrode 11 is grounded, and the collector electrodes 13 are supplied with a power supply voltage (collector voltage).

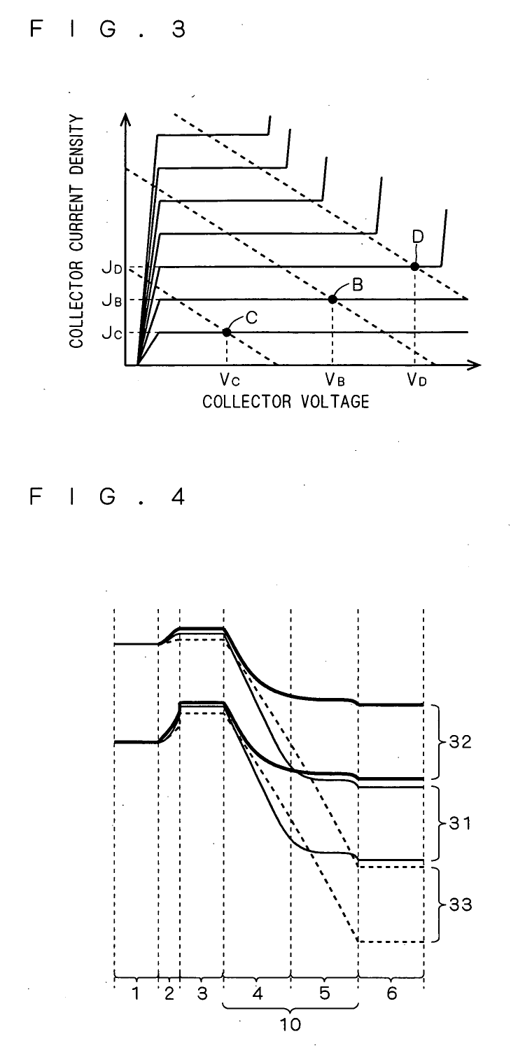

FIG. 2 depicts impurity concentration profiles taken along the line A-A′ in FIG. 1, which are represented by ionized net space charge. The direction of an arrow on the vertical axis indicates positive space charge (ionized donor N_{D}⁺), and the opposite direction indicates negative space charge (ionized acceptor N_{A}⁻). In FIG. 2, areas 21 to 27 indicate impurity concentration profiles of the N⁺-type emitter contact layer 1, N-type emitter layer 2, P⁺-type base layer 3, N-type collector layers 4 and 5, N⁺-type collector contact layer 6, and semi-insulation substrate 7, respectively. The height of each area indicates the impurity concentration of each layer, and the width of each area indicates the thickness of each layer (layer thickness).

FIG. 3 is a graph illustrating the collector current-collector voltage characteristic of the HBT 100 shown in FIG. 1. FIG. 3 indicates a voltage V_{B} that is a collector voltage under normal operation (normal collector voltage), a voltage V_{C} that is the lowest conceivable collector voltage to be used (lowest collector voltage), and a voltage V_{D} that is the highest conceivable collector voltage to be used (highest collector voltage). FIG. 3 also indicates current densities J_{B} to J_{D} of collector currents flowing through the HBT 100 correspondingly to the voltages V_{B} to V_{D}, respectively. FIG. 3 further indicates load lines, which are shown by the dotted lines, passing through a bias point B (V_{B}, J_{B}) to a bias point D (V_{D}, J_{D}), respectively, with a prescribed inclination. The inclination of those three load lines indicates the magnitude of the load, which is constant regardless of the collector voltage value.

In FIG. 2, the heights of the areas 24 and 25 indicate an impurity concentration N_{D1} of the N-type collector layer 4 and an impurity concentration N_{D2} of the N-type collector layer 5, respectively. Also in FIG. 2, the widths of the areas 24 and 25 indicate a layer thickness L₁ of the N-type collector layer 4 and a layer thickness L₂ of the N-type collector layer 5, respectively.

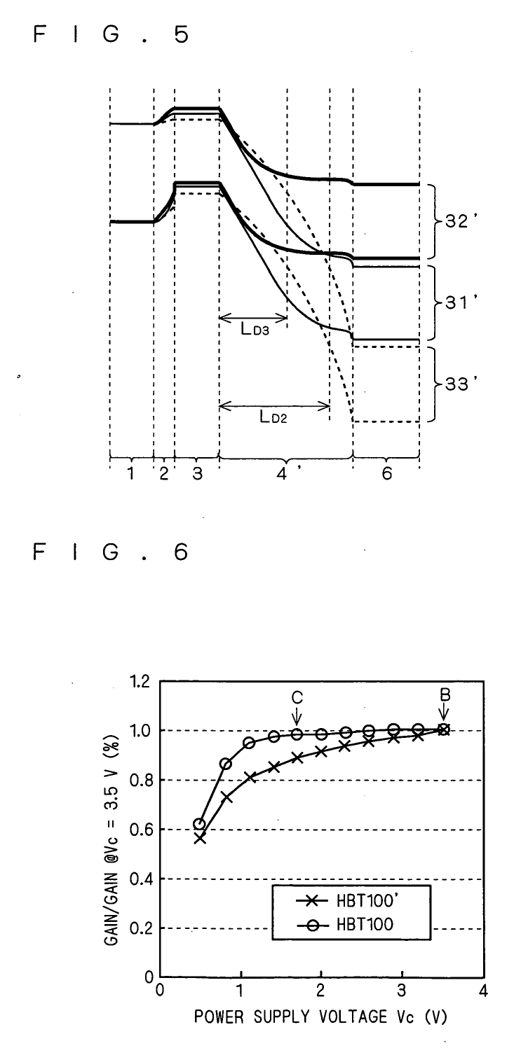

FIG. 4 illustrates band diagrams of the HBT 100. Diagrams 31 to 33 correspond to when the voltages V_{B} to V_{D} are applied, respectively, as a collector voltage. FIG. 4 and the figures that follow are based on the premise that the impurity concentration N_{D2} of the N-type collector layer 5 is five times the impurity concentration N_{D1} of the N-type collector layer 4.

The impurity concentration N_{D1} of the N-type collector layer 4 is equal to space charge concentration Q_{B}=J_{B}/(q×v_{SAT}) that is determined by the current density J_{B} at the bias point B, the quantity of elementary electric charge q, and saturated velocity v_{SAT} of electrons in the material of the N-type collector layer 10.

The layer thickness L₁ of the N-type collector layer 4 is equal to or a little smaller than a depletion layer thickness L_{D1}=[2×ε×(φi−V_{BASE})/(q×N_{D1}−J_{C}/v_{SAT})]^{-1/2} that is determined by the impurity concentration N_{D1}, a base voltage V_{BASE}, a built-in potential φ i of a pn junction between a base and a collector, and permittivity ε of the material of the N-type collector layer 10. A depletion layer thickness increases with an increase in collector voltage being applied. Thus, by determining the layer thickness L₁ of the N-type collector layer 4 in this manner, the N-type collector layer 4 is entirely depleted upon application of any of the voltages V_{B} to V_{D}. When the layer thickness L₁ of the N-type collector layer 4 is equal to the depletion layer thickness L_{D1}, the N-type collector layer 5 is not depleted upon application of the voltage V_{C}, but when the layer thickness L₁ of the N-type collector layer 4 is smaller than the depletion layer thickness L_{D1}, part of the N-type collector layer 5 making contact with the N-type collector layer 4 is a little depleted upon application of the voltage V_{C}.

The impurity concentration N_{D2} of the N-type collector layer 5 is higher to a sufficient degree than the space charge concentration Q_{B}=J_{B}/(q×V_{SAT}) that is determined by the current density J_{B} at the bias point B, the quantity of elementary electric charge q, and the saturated velocity V_{SAT} of electrons in the material of the N-type collector layer 10. The impurity concentration N_{D2} is also determined in such a manner that the N-type collector layer 5 is entirely depleted by the space charge effect of space charge concentration Q_{D}=J_{D}/(q×V_{SAT}) that is determined by the current density J_{D} at the bias point D, the quantity of elementary electric charge q, and the saturated velocity V_{SAT} of electrons in the material of the N-type collector layer 10, as well as the voltage V_{D}. By determining the impurity concentration N_{D2} of the N-type collector layer 5 in this manner, the N-type collector layer 5 is hardly depleted (the layer thickness of a depletion layer formed in the N-type collector layer 5 is not more than 20% with reference to the layer thickness of a depletion layer formed in the whole of the N-type collector layer 10) upon application of the voltage V_{B} or V_{C}, but is entirely depleted upon application of the voltage V_{D}.

As illustrated in FIG. 4, the N-type collector layer 4 is entirely depleted while the N-type collector layer 5 is hardly depleted in both the diagrams 31 and 32. Thus, a depletion layer thickness of the whole of the N-type collector layer 10 is almost equal to the layer thickness L₁ of the N-type collector layer 4 upon application of the voltage V_{B} or V_{C}. Accordingly, the depletion layer thickness of the whole of the N-type collector layer 10 hardly decreases even when the collector voltage is reduced from the voltage V_{B} under normal operation to the lowest conceivable voltage V_{C} to be used, preventing a significant increase in depletion layer capacitance C_{BC} that accompanies depletion, which is capacitance between a base and a collector as feedback capacitance between an input and an output. This prevents a gain in the common-emitter type high output amplifier using the HBT 100 from being reduced significantly from a predetermined value, thereby reducing collector voltage dependence of the gain in the common-emitter type high output amplifier.

As described above, both the N-type collector layers 4 and 5 are entirely depleted in the diagram 33 corresponding to when the voltage V_{D} is applied. The layer thickness L₂ of the N-type collector layer 5 is determined in such a manner that the HBT 100 has a sufficient ON breakdown voltage at the bias point D. Namely, the layer thickness (L₁+L₂) of the N-type collector layer 10 shall be such that a sufficient ON breakdown voltage is secured at the bias point D. When a semiconductor material for the collector is gallium arsenide (GaAs), for example, with a sufficient breakdown voltage being 30 V, the layer thickness (L₁+L₂) will be about 1 μM.

FIG. 5 illustrates, for comparison purposes, a band diagram of an HBT 100′ in which only an N-type collector layer 4′ is used instead of forming the N-type collector layer 5 in the HBT 100. Diagrams 31′ to 33′ correspond to when the voltages V_{B} to V_{D} are applied, respectively.

The thickness of the N-type collector layer 4′ shown in FIG. 5 is equal to the sum of the layer thickness L₁ of the N-type collector layer 4 and the layer thickness L₂ of the N-type collector layer 5. The N-type collector layer 4′ has the same characteristics as the N-type collector layer 4 except a layer thickness. Namely, the HBT 100′ is equivalent to the HBT 100 in which the N-type collector layer 5 is replaced by the N-type collector layer 4.

As shown by a depletion layer thickness L_{D2} of the diagram 31′ in FIG. 5, the N-type collector layer 4′ is mostly depleted upon application of the voltage V_{B}.

And as shown by a depletion layer thickness L_{D3} of the diagram 32′ in FIG. 5, almost half the N-type collector layer 4′ is depleted upon application of the voltage V_{C}. Accordingly, a depletion layer thickness of the collector layer is reduced from the depletion layer thickness L_{D2} to the depletion layer thickness L_{D3} in the HBT 100′ when a collector voltage being applied is reduced from the voltage V_{B} to the voltage V_{C}.

Meanwhile, as described above, the depletion layer thickness of the whole of the N-type collector layer 10 hardly decreases in the HBT 100 even when the collector voltage is reduced from the voltage V_{B} to the voltage V_{C}. In addition, the whole of the N-type collector layer 10 is depleted in the HBT 100 when the collector voltage is increased from the voltage V_{B} to the voltage V_{D}, as in the case of the N-type collector layer 4′ shown in FIG. 5. Therefore, the HBT 100 has the advantage over the HBT 100′ that the collector voltage dependence of a gain in the common-emitter type high output amplifier can be reduced while securing the ON breakdown voltage.

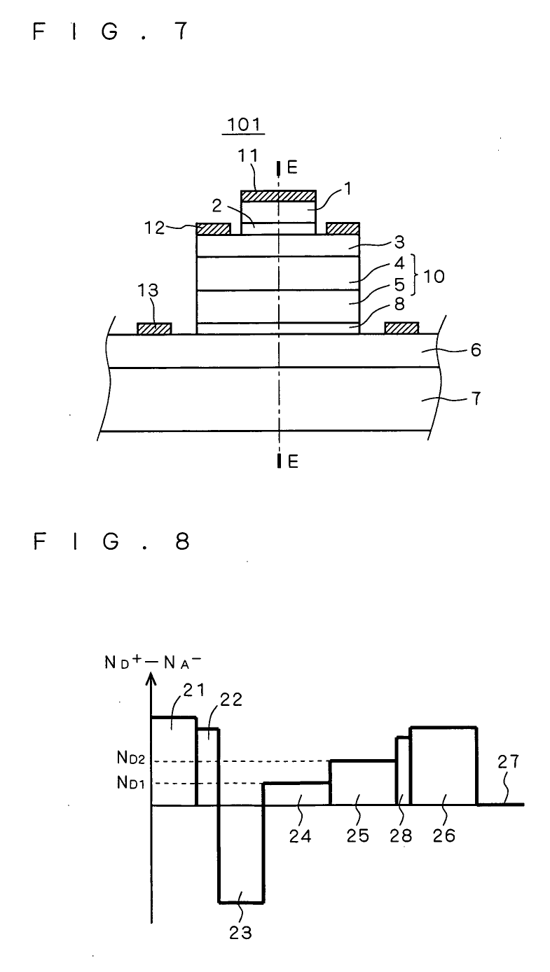

FIG. 6 is a graph illustrating the relationship between a collector voltage (power supply voltage) and a gain in the common-emitter type high output amplifiers formed by using the HBT 100 shown in FIG. 4 and the HBT 100′ shown in FIG. 5, respectively. The gain is represented by a ratio with reference to a gain with the collector voltage being the voltage V_{C}=3.5 V. In FIG. 6, the gain decreases substantially in the HBT 100′ when the collector voltage is reduced from the voltage V_{B} to the voltage V_{C}, whereas the gain hardly decreases in the HBT 100 when the collector voltage is reduced from the voltage V_{B} to the voltage V_{C}.

In such ways, in the HBT 100 according to the first preferred embodiment, the depletion layer thickness of the N-type collector layer 10 hardly decreases even when the collector voltage is reduced from the normal collector voltage to the lowest collector voltage. This prevents a significant increase in depletion layer capacitance C_{BC} that accompanies depletion, which is capacitance between a base and a collector as feedback capacitance between an input and an output. Accordingly, a gain is prevented from being reduced significantly from a predetermined value in the common-emitter type high output amplifier including the HBT 100 as an amplifying element. Namely, the collector voltage dependence of the gain in the common-emitter type high output amplifier can be reduced.

Further, because the whole of the N-type collector layer 10 is depleted when the collector voltage is increased from the normal collector voltage to the highest collector voltage, the ON breakdown voltage can be secured.

### Second Preferred Embodiment

The band diagrams of the HBT 100 according to the first preferred embodiment form, in the N-type collector layer 10, downward convex curves upon application of the voltages V_{B} and V_{C}, as shown by the diagrams 31 and 32 in FIG. 4, respectively, but form a slightly upward convex curve upon application of the voltage V_{D}, as shown by the diagram 33 in FIG. 4. In addition, space charge concentration based on the voltage V_{D} is higher than space charge concentrations based on the voltages V_{B} and V_{C}, respectively. Thus, the amount of change in the inclination of the band diagrams becomes maximum which renders an electric field maximum near an interface between the N-type collector layer 5 and the N⁺-type collector contact layer 6.

FIG. 7 is a cross-sectional view illustrating the structure of an HBT 101 according to a second preferred embodiment of this invention. The HBT 101 shown in FIG. 7 has a structure in which an N-type electric field relaxation layer 8 (first conductivity type electric field relaxation layer) including an N-type impurity is formed between the N-type collector layer 5 and the N⁺-type collector contact layer 6 in the HBT 100 shown in FIG. 1.

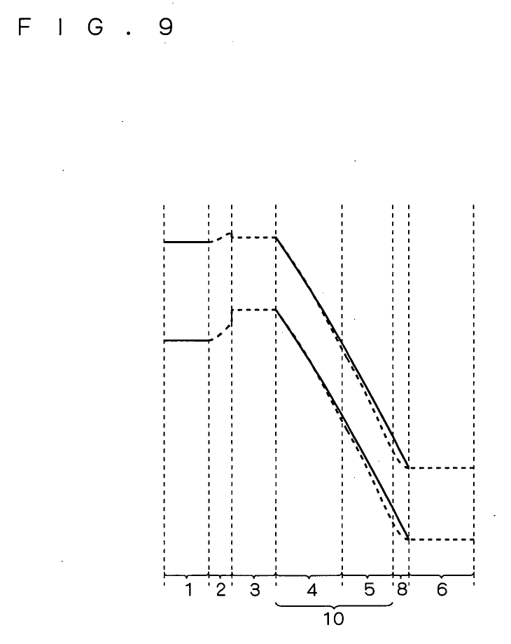

FIG. 8 depicts impurity concentration profiles taken along the line E-E′ in FIG. 7. Namely, in FIG. 8, an area 28 indicating an impurity concentration profile of the N-type electric field relaxation layer 8 is interposed between the areas 25 and 26 in FIG. 2.

As depicted in FIG. 8, the impurity concentration of the N-type electric field relaxation layer 8 (height of the area 28) is higher than the impurity concentration of the N-type collector layer 5 (height of the area 25) and lower than the impurity concentration of the N⁺-type collector contact layer 6 (height of the area 26). Consequently, as shown by the dashed lines in FIG. 9, the amount of change in the inclination of the band diagrams is relaxed by the N-type electric field relaxation layer 8, allowing the maximum value of the electric field to be reduced compared with curves shown by the solid lines (almost the same curves as the diagram 33 shown in FIG. 4) with no N-type electric field relaxation layer 8 being interposed. FIG. 9 illustrates band diagrams with the N-type collector layer 5 having an impurity concentration of 5×10¹⁶ cm⁻³, the N⁺-type collector contact layer 6 having an impurity concentration of 3×10¹⁸ cm⁻³, and the N-type electric field relaxation layer 8 having an impurity concentration of 1×10¹⁸ cm⁻³. Although there is a large difference in impurity concentration between the N-type collector layer 5 and the N⁺-type collector contact layer 6, the electric field can be relaxed by interposing the N-type electric field relaxation layer 8 having the impurity concentration almost midway between those of the N-type collector layer 5 and the N⁺-type collector contact layer 6 between the N-type collector layer 5 and the N⁺-type collector contact layer 6.

In such ways, the HBT 101 according to the second preferred embodiment has a structure in which the N-type electric field relaxation layer 8 including an N-type impurity is interposed between the N-type collector layer 5 and the N⁺-type collector contact layer 6 in the HBT 100 according to the first preferred embodiment. This allows the maximum value of the electric field to be reduced when the voltage V^{D} close to the ON breakdown voltage is applied as a collector voltage. Therefore, in addition to the effects of the first preferred embodiment, the ON breakdown voltage can be further increased.

While the invention has been shown and described in detail, the foregoing description is in all aspects illustrative and not restrictive. It is therefore understood that numerous modifications and variations can be devised without departing from the scope of the invention.

What is claimed is:

1. A heterojunction bipolar transistor comprising a first conductivity type collector layer, a first conductivity type emitter layer, and a second conductivity type base layer interposed between said first conductivity type collector layer and said first conductivity type emitter layer,
said first conductivity type collector layer including:
a first conductivity type first collector layer making contact with said second conductivity type base layer; and
a first conductivity type second collector layer making contact with said first conductivity type first collector layer, wherein
said first conductivity type first collector layer is entirely depleted upon being supplied with a lowest collector voltage, said lowest collector voltage being the lowest conceivable collector voltage to be used, and
said first conductivity type second collector layer has a carrier concentration higher than space charge concentration based on a normal collector voltage, and a depletion layer formed therein upon being supplied with said normal collector voltage, the ratio of the thickness of said depletion layer being not more than 20% with reference to the thickness of a depletion layer formed in the whole of said first conductivity type collector layer.

2. The heterojunction bipolar transistor according to claim 1, wherein said first conductivity type second collector layer has a carrier concentration lower than space charge concentration based on a highest collector voltage, said highest collector voltage being the highest conceivable collector voltage to be used, and is entirely depleted upon being supplied with said highest collector voltage.

3. The heterojunction bipolar transistor according to claim 1, further comprising:
a first conductivity type high carrier concentration collector contact layer making contact with said first conductivity type second collector layer; and
a first conductivity type electric field relaxation layer interposed between said fist conductivity type second collector layer and said first conductivity type high carrier concentration collector contact layer, and having an impurity concentration higher than said first conductivity type second collector layer and lower than said first conductivity type high carrier concentration collector contact layer.

4. The heterojunction bipolar transistor according to claim 2, further comprising:
a first conductivity type high carrier concentration collector contact layer making contact with said first conductivity type second collector layer; and
a first conductivity type electric field relaxation layer interposed between said fist conductivity type second collector layer and said first conductivity type high carrier concentration collector contact layer, and having an impurity concentration higher than said first conductivity type second collector layer and lower than said first conductivity type high carrier concentration collector contact layer.

5. An amplifier comprising the heterojunction bipolar transistor recited in claim 1 as an amplifying element.

6. An amplifier comprising the heterojunction bipolar transistor recited in claim 2 as an amplifying element.

7. An amplifier comprising the heterojunction bipolar transistor recited in claim 3 as an amplifying element.

8. An amplifier comprising the heterojunction bipolar transistor recited in claim 4 as an amplifying element.
